(19) United States
(12) Patent Application Publication
(10) Pub. No.: US 2023/0129549 A1
(43) Pub. Date: Apr. 27, 2023

(54) LONG BODY WINDING STRUCTURE AND RESPECTIVE LONG BODY

(71) Applicant: SUMITOMO WIRING SYSTEMS, LTD., Mie (JP)

(72) Inventors: Jumpei KAWAHARA, Mie (JP); Takuma HIBINO, Mie (JP); Harald Michael Lutsch, Wolfsburg (DE)

(21) Appl. No.: 17/964,977

(22) Filed: Oct. 13, 2022

(30) Foreign Application Priority Data
Oct. 22, 2021 (JP) 2021-173251

(51) Int. Cl. H01R 13/6581; H01R 13/6598

(52) U.S. Cl. CPC H01R 13/6581; H01R 13/6598

(57) ABSTRACT

A long body winding structure is provided with a long body and a reel. The long body includes a plurality of terminal modules arranged in parallel in a first direction, a first member, a second member and a third member. Each terminal module includes a plurality of first terminals arranged in parallel in the first direction and a dielectric member covering the plurality of first terminals. Each first terminal is an L-shaped rod-like piece including a first end part, a second end part and a first bent portion. The dielectric member covers the plurality of first terminals such that the first and second end parts of each first terminal are exposed. The first member is a strip-like member coupling adjacent ones of the first end parts to link the plurality of terminal modules.

### CROSS-REFERENCE TO RELATED APPLICATIONS

This application is based on and claims priority from Japanese Patent Application No. 2021-173251, filed on Oct. 22, 2021, with the Japan Patent Office, the disclosure of which is incorporated herein in its entirety by reference.

### TECHNICAL FIELD

The present disclosure relates to a long body winding structure and to a respective long body.

### BACKGROUND

Japanese Patent Laid-open Publication No. 2018-006152 discloses a shield connector provided with a dielectric module and an outer conductor. The dielectric module is configured by assembling a dielectric made of synthetic resin and a plurality of elongated terminal fittings bent into an L shape. The dielectric is a block-like body and includes a plurality of mounting holes penetrating in a front-rear direction. The plurality of terminal fittings are mounted in the dielectric by being inserted into the mounting holes. The outer conductor includes a box-shaped module accommodating portion formed, such as by bending a metal plate material. The module accommodating portion is formed with an insertion opening. The dielectric module is inserted into the insertion opening and accommodated into the module accommodating portion.

### SUMMARY

A shield connector is generally configured by individually fabricating terminal fittings, a dielectric and an outer conductor and successively assembling the dielectric and the outer conductor with the terminal fittings as disclosed in Japanese Patent Laid-open Publication No. 2018-006152. The shield connector configured by further assembling a housing is a final product to be actually used. Note that, in the case of configuring a product by successively assembling individually fabricated members, a dedicated machine for assembling each member is necessary. In the case of configuring a product by successively assembling the individually fabricated members, an intermediate product or final product fabricated in each step needs to be individually managed during movements between a step of fabricating terminal fittings, a step of assembling a dielectric outside the terminal fittings and a step of assembling an outer conductor outside the dielectric.

In the following description, the shield connector particularly is referred to as a terminal module, the terminal fitting particularly is referred to as a terminal, the dielectric particularly is referred to as a dielectric member and the outer conductor particularly is referred to as a shield member.

One object of the present disclosure is to provide a long body winding structure facilitating the handling of terminal modules and excellent in productivity in a terminal module manufacturing process.

This object is solved according to the invention by the features of the independent claims. Particular embodiments of the invention are subject of the dependent claims.

The present disclosure is directed to a long body winding structure with a long body and a reel having the long body (to be) wound thereon, wherein the long body includes a plurality of terminal modules arranged substantially in parallel in a first direction, a first member, a second member and a third member, each of the plurality of terminal modules includes a plurality of first terminals arranged substantially in parallel in the first direction and a dielectric member at least partly covering the plurality of first terminals, each of the plurality of first terminals substantially is an L-shaped rod-like piece including a first end part, a second end part and a first bent portion, a first section from the first end part to the first bent portion is arranged to substantially extend in a second direction intersecting, particularly substantially orthogonal to the first direction, a second section from the second end part to the first bent portion is arranged to substantially extend in a third direction intersecting both the first direction and the second direction, the dielectric member at least partly covers the plurality of first terminals such that the first and second end parts of each of the plurality of first terminals are exposed, the first member comprises, particularly is a strip-like or oblong member coupling adjacent ones of the first end parts to link the plurality of terminal modules, the second member has a base end part coupled to the first member and is arranged to substantially extend in the same direction as the second sections, and the third member couples the second end parts in each of the plurality of terminal modules.

First, embodiments of the present disclosure are listed and described.

(1) A long body winding structure according to an embodiment of the present disclosure is provided with a long body and a reel having the long body wound thereon, wherein the long body includes a plurality of terminal modules arranged in parallel in a first direction, a first member, a second member and a third member, each of the plurality of terminal modules includes a plurality of first terminals arranged in parallel in the first direction and a dielectric member covering the plurality of first terminals, each of the plurality of first terminals is an L-shaped rod-like piece including a first end part, a second end part and a first bent portion, a first section from the first end part to the first bent portion is arranged to extend in a second direction orthogonal to the first direction, a second section from the second end part to the first bent portion is arranged to extend in a third direction intersecting both the first direction and the second direction, the dielectric member covers the plurality of first terminals such that the first and second end parts of each of the plurality of first terminals are exposed, the first member is a strip-like member coupling adjacent ones of the first end parts to link the plurality of terminal modules, the second member has a base end part coupled to the first member and is arranged to extend in the same direction as the second sections, and the third member couples the second end parts in each of the plurality of terminal modules.

The long body winding structure according to the present disclosure facilitates the handling of the terminal modules in a terminal module manufacturing process. Since the plurality of terminal modules are coupled by the first member to configure the long body in the long body winding structure, the plurality of terminal modules need not be individually managed.

Moreover, the long body winding structure according to the present disclosure is excellent in productivity in the terminal module manufacturing process. In the long body winding structure, the plurality of terminal modules can be manufactured in a state of the long body. For example, in the long body winding structure, shield members to be described later can be arranged while the long body is rewound, and the plurality of terminal modules are obtained in the state of the long body. Since the plurality of terminal modules can be manufactured in the state of the long body in the long body winding structure, a general-purpose machine can be used as a machine for arranging constituent members, e.g. the shield members, of the terminal modules. In the long body winding structure, during a movement between a step of arranging the shield members outside the dielectric members and a step of assembling connectors using the terminal modules, products fabricated in each step can be managed in a state wound on the reel.

(2) As one aspect of the long body winding structure of the present disclosure, each of the plurality of terminal modules includes a plurality of second terminals arranged to sandwich the plurality of first terminals from outside in the first direction, each of the plurality of second terminals substantially is an L-shaped rod-like piece including a third end part, a fourth end part and a second bent portion, a section from the third end part to the second bent portion is arranged to substantially extend in the second direction, a section from the fourth end part to the second bent portion is arranged to substantially extend in the third direction, the long body includes a fourth member coupling adjacent ones of the third end parts in adjacent ones of the plurality of terminal modules, and the third member substantially couples the second end parts and the fourth end parts in each of the plurality of terminal modules.

According to the above aspect, even if each terminal module includes the second terminals, the plurality of terminal modules are easily wound in the form of the long body on the reel.

(3) As one aspect of the long body winding structure of the present disclosure, each of the plurality of terminal modules includes at least one shield member at least partly covering at least the dielectric member.

Even if each terminal module includes the shield member, the handling of the terminal modules is facilitated and productivity is excellent in the terminal module manufacturing process as described in (1) above.

(4) As one aspect of the long body winding structure of the present disclosure, a length from the first section to a tip of the second member and a length from the first section to a tip of the third member substantially are equal.

According to the above aspect, the long body is hardly inclined when being wound on the reel, and the long body is easily wound on the reel.

(5) As one aspect of the long body winding structure of the present disclosure, the second member substantially is parallel to the second sections.

According to the above aspect, the long body is hardly inclined when being wound on the reel, and the long body is easily wound on the reel.

(6) As one aspect of the long body winding structure of the present disclosure, a thickness direction of the first member substantially is the third direction.

According to the above aspect, the first member is bent flatwise when the long body is wound on the reel, and the long body is easily wound on the reel. Flatwise bending is bending performed with a surface on a long side of a transverse cross-section of the first member, which is a strip-like member, located on an inner side.

(7) As one aspect of the long body winding structure of the present disclosure, a gap is provided between the third members in adjacent ones of the plurality of terminal modules.

According to the above aspect, the long body is easily bent on a side where the third member is arranged and the long body is easily wound on the reel.

(8) As one aspect of the long body winding structure of the present disclosure, the long body is wound in multiple layers on the reel, and the long body winding structure is provided with an intervening member arranged between turns of the long body adjacent in a radial direction of the reel.

According to the above aspect, it is easily suppressed that the turn on an inner peripheral side of the long body and the turn on an outer peripheral side rub against each other to damage the terminal modules.

(9) As one aspect of the long body winding structure of the present disclosure of (8) described above, the intervening member is made of a tape material continuous in a winding direction.

According to the above aspect, the intervening member is easily arranged between the turns of the long body.

(10) As one aspect of the long body winding structure of the present disclosure, the long body is so wound that a tip of the second member and a tip of the third member are facing radially outwardly of the reel.

According to the above aspect, since the dielectric members and, further, the shield members are located on a radially inner side of the reel, the long body is easily wound on the reel.

(11) As one aspect of the long body winding structure of the present disclosure, the reel includes a winding drum and one or more flange portions extending the winding drum, preferably from respective end parts of the winding drum, and wherein a length between the two flange portions preferably substantially is equal to or less than about 1.5-fold of a width of the long body. More specifically, the reel includes a winding drum and two flange portions extending from respective end parts of the winding drum, and a length between the two flange portions is equal to or less than 1.5-fold of a width of the long body.

According to the above aspect, the long body is hardly shifted in a width direction when being wound on the reel, and the long body is easily wound on the reel.

The present disclosure is also directed to a long body, which includes a plurality of terminal modules arranged substantially in parallel in a first direction, a first member, a second member and a third member, wherein: each of the plurality of terminal modules includes a plurality of first terminals arranged substantially in parallel in the first direction and a dielectric member at least partly covering the plurality of first terminals, each of the plurality of first terminals substantially is an L-shaped rod-like piece including a first end part, a second end part and a first bent portion, a first section from the first end part to the first bent portion is arranged to substantially extend in a second direction intersecting, particularly substantially orthogonal to the first direction, a second section from the second end part to the first bent portion is arranged to substantially extend in a third direction intersecting both the first direction and the second direction, the dielectric member at least partly covers the plurality of first terminals such that the first and second end parts of each of the plurality of first terminals are exposed, the first member comprises, particularly is a strip-like or oblong member coupling adjacent ones of the first end parts to link the plurality of terminal modules, the second member has a base end part coupled to the first member and is arranged to substantially extend in the same direction as the second sections, and the third member couples the second end parts in each of the plurality of terminal modules.

Specifically, the above long body may be configured according to the present disclosure of (1) to (11) described above.

The long body winding structure of the present disclosure facilitates the handling of the terminal modules and excellent in productivity in a terminal module manufacturing process.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic configuration diagram of a long body winding structure according to an embodiment.

FIG. 2 is a partial enlarged view showing an example of a long body provided in the long body winding structure according to the embodiment.

FIG. 3 is a partial enlarged view showing a state where dielectric members are omitted in the long body shown in FIG. 2.

FIG. 4 is a partial enlarged view showing another example of the long body provided in the long body winding structure according to the embodiment.

FIG. 5 is a diagram showing a long body winding form in the long body winding structure according to the embodiment.

FIG. 6 is a diagram showing a state of the long body in the long body winding structure according to the embodiment.

FIG. 7 is a diagram showing a first step and a second step for obtaining the long body winding structure according to the embodiment.

FIG. 8 is a diagram showing the first step shown in FIG. 7.

FIG. 9 is a diagram showing a third step for obtaining the long body winding structure according to the embodiment.

FIG. 10 is a schematic perspective view showing a final form of a terminal module.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

<Long Body Winding Structure>

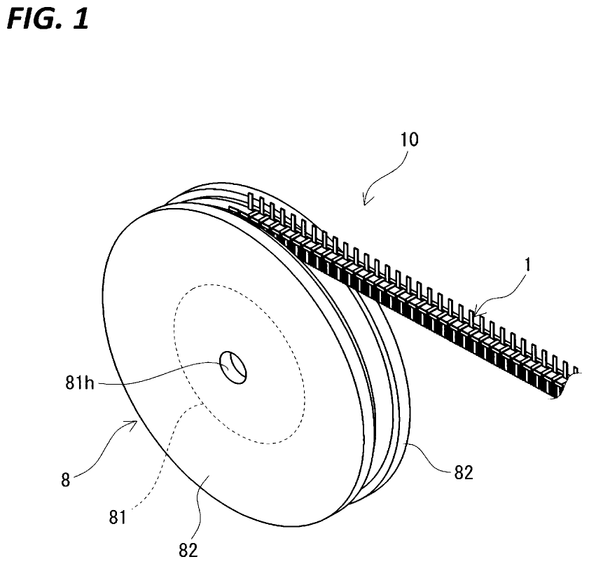

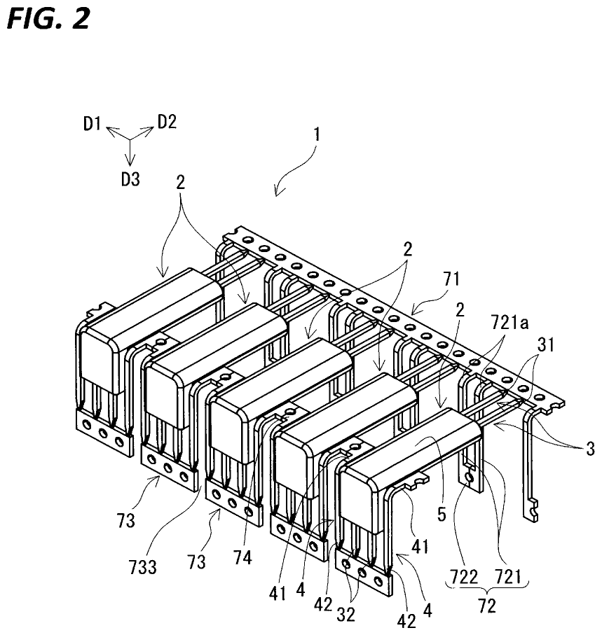

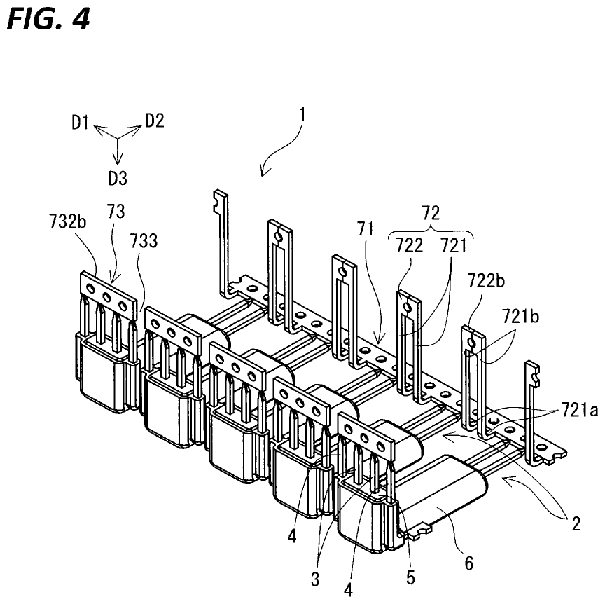

With reference to FIGS. 1 to 6, a long body winding structure according to the embodiment is described. The long body winding structure is merely referred to as a winding structure 10 below. As shown in FIG. 1, the winding structure 10 particularly includes a long body 1 and a reel 8. One of features of the winding structure 10 is that a plurality of terminal modules 2 are coupled by a first member 71 to configure the long body 1 as shown in FIGS. 2 and 4. Another of the features of the winding structure 10 is that, as shown in FIGS. 2 and 4, one or more second members 72 and/or one or more third members 73 are provided so that the long body 1 can be wound on the reel 8 shown in FIG. 1. The configuration of the reel 8 is first described and, then, the configuration of the long body 1 is described below.

<<Reel>>

As shown in FIG. 1, the reel 8 includes a winding drum 81 and one or more (e.g. two) flange portions 82. The long body 1 is wound on the winding drum 81. A hole 81h particularly is provided in a center of the winding drum 81. The winding drum 81 is freely rotatable about a rotary shaft inserted or insertable into the hole 81h. Specifically, the plurality of (e.g. two) flange portions 82 are arranged at an interval particularly on both end parts in an axial direction of the winding drum 81. The flange portion 82 of this example is a disk-like member.

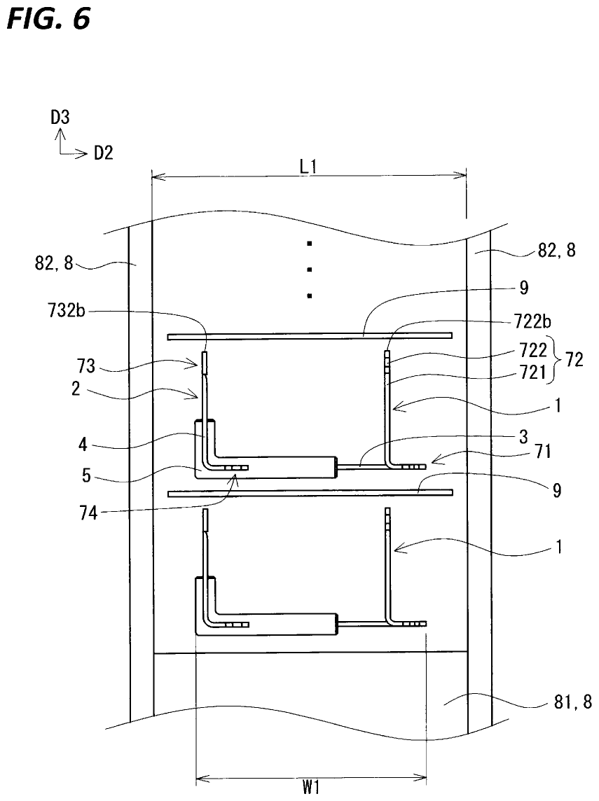

As shown in FIG. 6, the long body 1 at least partly is accommodated in a space adjacent to one or more two flange portions 82, particularly at least partly between adjacent two flange portions 82. A length or distance L1 between the two flange portions 82 particularly is more than a width W1 of the long body 1. The length L1 between the two flange portions 82 is, for example, equal to or less than about 1.5-fold of the width W1 of the long body 1. Since the length L1 is equal to or less than about 1.5-fold of the width W1, the long body 1 is hardly shifted in a width direction when being wound on the reel 8, and the long body 1 is easily wound on the reel 8.

Specifically, the length L1 between the two flange portions 82 can be equal to or less than about 1.25-fold of the width W1. If the long body 1 is wound in multiple layers on the reel 8 and an intervening member 9 particularly is at least partly arranged between turns of the long body 1 adjacent in a radial direction of the reel 8 as shown in FIG. 6, the length L1 between the two flange portions 82 particularly is substantially equal to a width of the intervening member 9. Since the length L1 is substantially equal to the width of the intervening member 9, constituent members, e.g. first terminals 3 to be described later, of the terminal modules 2 hardly protrude from the intervening member 9 and the long body 1 is easily wound on the reel 8 even if the long body 1 is shifted in the width direction.

<<Long Body>>

As shown in FIGS. 2 and 4, the long body 1 includes a plurality of the terminal modules 2, the first member 71, the second member(s) 72 and the third member(s) 73. The long body 1 of this example further includes fourth members 74. A difference between the long body 1 shown in FIG. 2 and the long body 1 shown in FIG. 4 particularly is whether or not each terminal module 2 includes a shield member 6. The long body 1 shown in FIG. 2 include no shield member. The long body 1 shown in FIG. 4 includes the shield members 6. FIG. 4 shows a vertically inverted state of the long body 1 shown in FIG. 2.

The long body 1 has a first direction D1, a second direction D2 and a third direction D3. The first direction D1 substantially is a longitudinal direction of the long body 1. The second direction D2 substantially is a direction orthogonal to the first direction D1. The second direction D2 of this example substantially is the width direction of the long body 1. The third direction D3 substantially is a direction intersecting both the first direction D1 and the second direction D2. The third direction D3 of this example is a direction substantially orthogonal to both the first direction D1 and the second direction D2. The third direction D3 of this example substantially is or corresponds to the radial direction of the reel 8 with the long body 1 wound on the reel 8 (FIG. 1).

[Terminal Modules]

The plurality of terminal modules 2 particularly substantially are arranged in parallel in the first direction D1. Each of the plurality of terminal modules 2 particularly has the substantially same form. Specifically, the (particularly each) terminal module 2 includes the first terminal 3 and a dielectric member 5. Each terminal module 2 of this example further includes one or more second terminals 4. As shown in FIG. 4, the winding structure 10 particularly may further include the shield members 6 in the terminal modules 2.

(First Terminals)

Each terminal module 2 particularly includes a plurality of the first terminals 3. In this example, one terminal module 2 is provided with two first terminals 3. The plurality of first terminals 3 particularly substantially are arranged in parallel in the first direction D1. The plurality of first terminals 3 are arranged at an interval.

Each first terminal 3 particularly is or serves as a signal terminal.

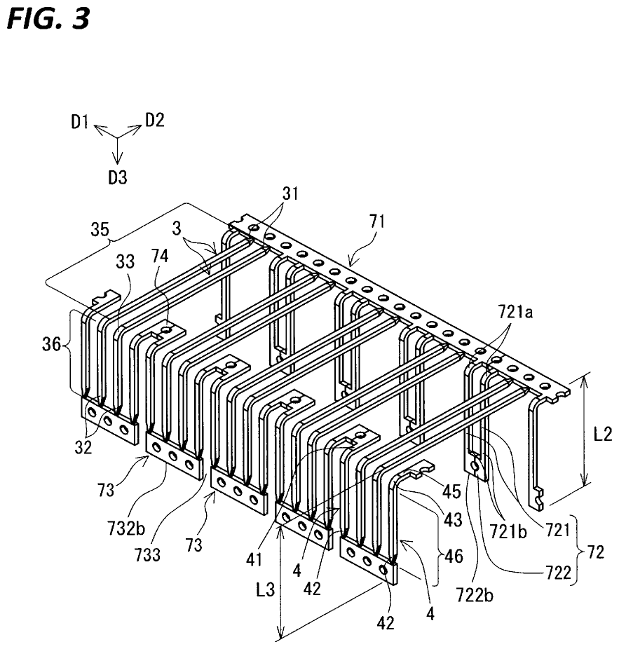

As shown in FIG. 3, the (particularly each) first terminal 3 particularly substantially is an L-shaped rod-like piece including a first end part 31, a second end part 32 and at least one (first) bent portion 33. A first section 35 from the first end part 31 to the first bent portion 33 particularly is arranged to substantially extend in the second direction D2.

A second section 36 from the second end part 31 to the first bent portion 33 particularly is arranged to substantially extend in the third direction D3.

In this example, the first section 35 particularly is longer than the second section 36.

(Second Terminals)

The (particularly each) terminal module 2 includes a plurality of the second terminals 4. In this example, one terminal module 2 particularly is provided with two second terminals 4.

Specifically, the plurality of second terminals 4, in this example, two second terminals 4 are arranged to sandwich the plurality of first terminals 3 from outside in the first direction D1.

The plurality of first terminals 3 and the plurality of second terminals 4 particularly are arranged substantially in parallel in the first direction D1. The plurality of second terminals 4 are arranged at intervals from the first terminals 3.

Each second terminal 4 particularly is or serves as a ground terminal.

As shown in FIG. 3, the (particularly each) second terminal 4 particularly substantially is an L-shaped rod-like piece including a third end part 41, a fourth end part 42 and at least one (second) bent portion 43.

A first section 45 from the third end part 41 to the second bent portion 43 particularly is arranged to substantially extend in the second direction D2.

A second section 46 from the fourth end part 41 to the second bent portion 43 particularly is arranged to substantially extend in the third direction D3. In this example, the first section 45 is shorter than the second section 46.

Specifically, the first section 45 of this example is about 50% or less, further about 25% or less of the length in the second direction D2 of the first section 35 in the first terminal 3.

The second section 46 of this example particularly has a length substantially equal to that of the second section 36 in the first terminal 3.

[Dielectric Members]

As shown in FIG. 2, the dielectric member 5 particularly is a resin molded body provided to at least partly cover the plurality of first terminals 3.

Specifically, the dielectric member 5 covers an intermediate region including the first bent portions 33 (FIG. 3) to expose the first end parts 31 and the second end parts 32 of the respective first terminals 3.

The dielectric member 5 of this example particularly substantially is bent into an L shape to correspond to the bent shape of the first terminals 3.

The dielectric member 5 particularly is provided to ensure electrical insulation between the first terminals 3 and the second terminals 4 and/or between the respective terminals and the shield member 6 (FIG. 4) to be described later.

If each terminal module 2 includes the shield member 6 (FIG. 4), the dielectric member 5 particularly is at least partly arranged between the first terminals 3 and the shield member 6. The dielectric member 5 at least partly is also arranged between the adjacent first terminals 3. The dielectric member 5 at least partly is also arranged between the first terminals 3 and the second terminals 4.

The dielectric member 5 particularly is designed to achieve characteristic impedance matching at a frequency of communication signals transmitted in the first terminals 3.

The dielectric member 5 particularly is made of an insulating material such as a resin.

(Shield Members)

As shown in FIG. 4, the shield member 6 particularly is provided to at least partly cover at least the dielectric member 5.

The shield member 6 of this example also at least partly covers the plurality of second terminals 4.

The shield member 6 of this example particularly substantially is bent into an L shape to correspond to the bent shape of the first terminals 3.

Specifically, the first and second end parts 31, 32 of the first terminals 3 are exposed from the shield member 6. The third and fourth end parts 41, 42 of the second terminals 4 particularly are exposed from the shield member 6.

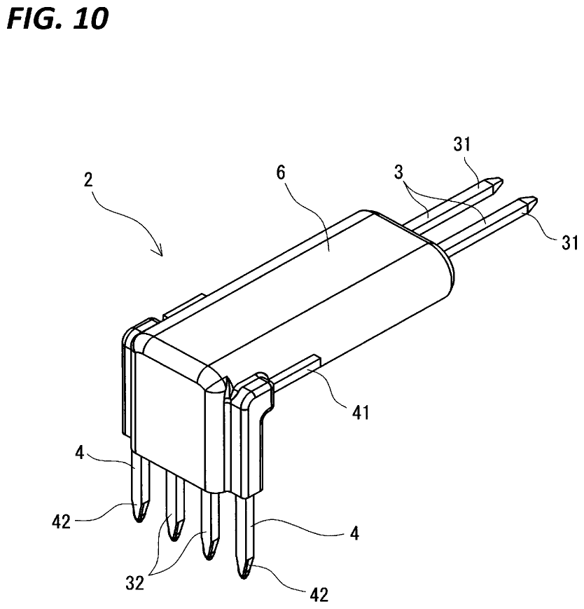

As shown in FIG. 10, the third end parts 41 of the second terminals 4 particularly are in contact with the shield member 6.

The shield member 6 particularly has shielding performance of shielding noise leaking from the first terminals 3.

The shield member 6 is, for example, at least partly made of a casting material. Gaps are hardly formed on the peripheral surface of the shield member 6 made of the casting material. The shield member 6 made of the casting material is excellent in shielding performance. The casting material of the shield member 6 is not particularly limited as long as it is a metal having a high electrical conductivity. For example, various pure metals or alloys excellent in electrical conductivity and strength can be suitably used as the material of the shield member 6. The casting material of the shield member 6 is preferably a zinc alloy.

Note that the shield member 6 may be at least partly made of an electrically conductive resin material. A composite material in which an electrically conductive filler is dispersed in a resin material can be cited as the electrically conductive resin material. Polybutylene terephthalate (PBT) and the like can be cited as the electrically conductive resin material. Carbon black, metals and the like can be cited as a material of the electrically conductive filler.

[First Member]

As shown in FIGS. 2 and 4, the first member 71 couples (particularly the first end parts 31 of) the adjacent first terminals 3 to link the plurality of terminal modules 2. The first member 71 particularly substantially is a strip-like member.

A longitudinal direction of the first member 71 is that of the long body 1. The longitudinal direction of the first member 71 particularly is the first direction D1. A width direction of the first member 71 particularly is the second direction D2. A thickness direction of the first member 71 particularly is the third direction D3.

A thickness of the first member 71 particularly is smaller than a width. The first end part 31 of this example is coupled to a first surface of the first member 71 facing in the second direction D2.

With the long body 1 wound on the reel 8 (FIG. 1), the first member 71 substantially is bent flatwise. Flatwise bending particularly is easiest bending.

The first member 71 particularly includes one or more, particularly a plurality of circular holes particularly provided at intervals in the first direction D1. The plurality of holes are used, for example, in winding and rewinding the long body 1 on and from the reel 8. That is, the first member 71 particularly can function as a carrier.

[Second Members]

As shown in FIGS. 2 and 4, the second member 72 particularly includes one or more base end parts 721a coupled to the first member 71. The second member 72 is supported on the first member 71 at the base end part(s) 721a.

The second member 72 particularly is arranged to substantially extend in the same direction as the second sections 36 (FIG. 3) of the first terminals 3. The second member 72 of this example substantially is arranged in parallel to the second sections 36 (FIG. 3). The second member 72 may not be in parallel to the second sections 36 (FIG. 3).

In this example, a plurality of the second members 72 particularly are provided. The (particularly each) second member 72 particularly is arranged between the first end parts 31 of the adjacent first terminals 3 in the adjacent terminal modules 2.

The (particularly each) second member 72 of this example is arranged to substantially face the second sections 46 (FIG. 3) of the second terminals 4.

The (particularly each) second member 72 of this example particularly includes one or more, particularly a plurality of rod-like pieces 721 and/or a coupling portion 722. Each second member 72 of this example includes two rod-like pieces 721.

The plurality of rod-like pieces 721 particularly are arranged substantially in parallel in the first direction D1. The base end part 721a of each rod-like piece 721 particularly is coupled to the first member 71. The base end part 721a of this example is coupled to the first surface of the first member 71 substantially facing in the second direction D2.

The (particularly each) rod-like piece 721 of this example particularly includes a bent portion near the base end part 721a. The (particularly each) rod-like piece 721 particularly extends in the substantially same direction as the second sections 36 (FIG. 3) by having the bent portion.

The coupling portion 722 particularly couples tip parts 721b of the plurality of rod-like pieces 721 in each second member 72.

The coupling portion 722 of this example particularly is a substantially rectangular plate piece. One circular hole particularly is formed in a center of the coupling portion 72.

[Third Members]

As shown in FIGS. 2 and 4, the third member 73 particularly couples two or more of first terminals 3. Specifically, the third member 73 couples the second end parts 32 of the plurality of first terminals 3 particularly in each terminal module 2.

The third member 73 of this example couples the second end parts 32 of the plurality of first terminals 3 and/or the fourth end parts 42 of the plurality of second terminals 4 in each terminal module 2.

In this example, a plurality of third members 73 are provided. Each third member 73 particularly is provided for each of the plurality of terminal modules 2.

A gap 733 particularly is provided between the third members 73 in the adjacent terminal modules 2.

The third member 73 of this example particularly is a short strip-like member extending in the first direction D1.

The third member 73 particularly includes one or more, particularly a plurality of circular holes particularly provided at intervals in the first direction D1

A longitudinal direction of the third member 73 particularly substantially is that of the long body 1.

The longitudinal direction of the third member 73 particularly is the first direction D1. A width direction of the third member 73 particularly is the third direction D3. A thickness direction of the third member 73 particularly is the second direction D2.

A thickness of the third member 73 particularly is smaller than a width.

The second end parts 32 and the fourth end parts 42 of this example are coupled to a first surface of the third member 73 substantially facing in the third direction D3.

With the long body 1 wound on the reel 8 (FIG. 1), the third members 73 particularly are bent edgewise. Edgewise bending is bending performed with a surface on a short side of a transverse cross-section of the third member 73, which is a strip-like member, located on an inner side. Edgewise bending is harder than flatwise bending. Even if the third members 73 are bent edgewise, the long body 1 itself is easily bent since the one or more gaps are provided between the third members 73 in the adjacent terminal modules 2.

A length L2 and a length L3 shown in FIG. 3 particularly are preferably equal. In FIG. 3, the dielectric members 5 are not shown. The length L2 particularly is a length from the first section 35 of the first terminal 3 to a tip 722b of the second member 72. The tip 722b of this example is a surface of the coupling portion 722 substantially facing in the third direction D3. The length L3 particularly is a length from the first section 35 to a tip 732b of the third member 73. The tip 732b of this example is a surface of the third member 73 substantially facing in the third direction D3.

[Fourth Members]

As shown in FIGS. 2 and 4, the fourth member 74 particularly couples (particularly the third end parts 41 of) the adjacent second terminals 4 in the adjacent terminal modules 2.

The fourth member 74 particularly is, for example, a substantially rectangular plate piece. At least one circular hole is formed in (e.g. substantially a center of) the fourth member 74.

A thickness of the fourth member 74 in the third direction D3 preferably corresponds to a thickness of the second terminal 4.

The first member 71, the second members 72, the third members 73 and/or the fourth members 74 particularly are made of the same metal as the first terminals 3.

<<Winding Form of Long Body>>

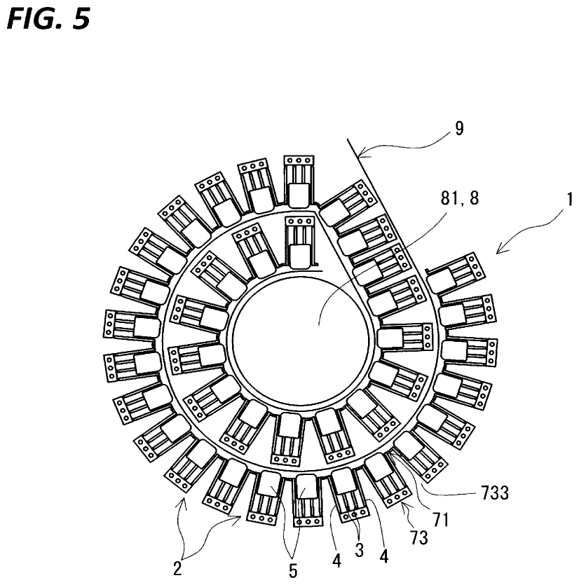

The long body 1 particularly is wound in multiple layers on the winding drum 81 of the reel 8, for example, as shown in FIGS. 5 and 6. The long body 1 shown in FIGS. 5 and 6 particularly is the long body 1 shown in FIG. 2.

The long body 1 shown in FIGS. 5 and 6 particularly includes no shield member 6 shown in FIG. 4.

If the long body 1 is wound in multiple layers, the intervening member 9 is preferably arranged at least partly between turns of the long body 1 adjacent in the radial direction of the reel 8. The intervening member 9 is so arranged that the turn on an inner peripheral side of the long body 1 wound in multiple layers and the turn on an outer peripheral side thereof do not rub against each other.

A material which is hardly broken even if being rubbed against the long body 1 can be appropriately selected as a material of the intervening member 9.

A thickness of the intervening member 9 can be appropriately selected so that the intervening member 9 is not broken and/or substantially does not hinder the winding of the long body 1 when the intervening member 9 is wound on the reel 8 together with the long body 1.

A width of the intervening member 9 particularly is equal to or more than the width W1 (FIG. 6) of the long body 1.

The intervening member 9 of this example is made of a tape material continuous in a winding direction. The intervening member 9 of this example is made of a tape material having a uniform thickness in the width direction. The intervening member 9 may be made of a tape material having a thickness varying in the width direction.

For example, if the second members 72 and the second sections 36 (FIG. 3) of the first terminals 3 particularly are not in parallel or if the lengths L2 and L3 shown in FIG. 3 are different, the long body 1 is easily inclined. In such a case, the intervening member 9 is preferably made of a tape material having a thickness varying in the width direction particularly so that the inclination of the long body 1 can be substantially absorbed or compensated.

The intervening member 9 is, for example, made of insulating paper.

The long body 1 is, for example, so wound particularly that the tips 722b of the second members 72 and the tips 732b of the third members 73 are substantially facing radially outwardly of the reel 8 as shown in FIG. 6. In this case, the dielectric members 5 particularly are located on a radially inner side of the reel 8.

<<State of Long Body>>

As shown in FIG. 6, with the long body 1 wound on the winding drum 81, member(s) of the long body 1 capable of contacting the winding drum 81, the flange portions 82 or the intervening member 9 particularly are the dielectric members 5, the first member 71 and/or the second members 72.

If the dielectric members 5 particularly are at least partly covered with the shield members 6 (FIG. 4), the shield members 6 can contact the winding drum 81, the flange portions 82 and/or the intervening member 9.

With the long body 1 wound on the winding drum 81, the first terminals 3 and the second terminals 4 particularly hardly contact the winding drum 81, the flange portions 82 and the intervening member 9.

The dielectric members 5 particularly are arranged outside the first sections 35 (FIG. 3) of the first terminals 3. Thus, one or more steps are formed between surface(s) substantially facing in the third direction D3 of the first sections 35 in region(s) exposed from the dielectric member(s) 5 and surface(s) of the dielectric member(s) 5 substantially facing in the third direction D3.

Due to these one or more steps, the first terminals 3 particularly hardly contact the winding drum 81 or the intervening member 9.

The dielectric members 5 particularly are arranged outside the second sections 36 (FIG. 3) of the first terminals 3. Thus, one or more steps are formed between surface(s) substantially facing in the second direction D2 of the second section(s) 36 in region(s) exposed from the dielectric member(s) 5 and surface(s) of the dielectric member(s) 5 substantially facing in the second direction D2.

Due to these one or more steps, the first terminals 3 particularly hardly contact the flange portions 82.

The second terminals 4 particularly are exposed from the dielectric members 5, but substantially arranged in parallel to the first terminals 3. Thus, the second terminals 4 particularly hardly contact the winding drum 81, the flange portions 82 or the intervening member 9 due to the above steps.

The first member 71 particularly is coupled to the first end parts 31 of the first terminals 3. A surface of the first member 71 substantially facing in the second direction D2 particularly is substantially facing the flange portion 82. Thus, the first end parts 31 of the first terminals 3 particularly are made less likely to contact the flange portion 82 by the contact of the first member 71 with the flange portion 82.

The second members 72 particularly are so coupled to the first member 71 as to substantially extend in the same direction as the second sections 36 (FIG. 3) of the first terminals 3. Specifically, the tips 722b of the second members 72 substantially are facing the intervening member 9. Thus, the first end parts 31 of the first terminals 3 particularly are made less likely to contact the intervening member 9 by the contact of the tips 722b of the second members 72 with the intervening member 9.

The third members 73 particularly are coupled to the second end parts 32 of the first terminals 3. Specifically, the tips 732b of the third members 73 are substantially facing the intervening member 9. Thus, the second end parts 32 of the first terminals 3 particularly are made less likely to contact the intervening member 9 by the contact of the tips 732b of the third members 73 with the intervening member 9.

<Manufacturing Method of Long Body Winding Structure>

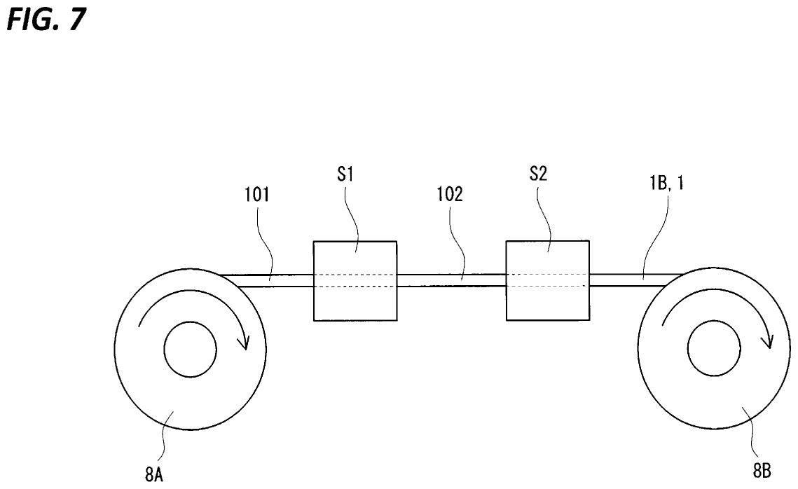

With reference to FIGS. 7 to 9, a particular manufacturing method of the aforementioned winding structure 10 is described. The winding structure in which the long body 1 shown in FIG. 2 is wound on the reel 8 is obtained by successively performing a first step S1 and a second step S2 shown in FIG. 7.

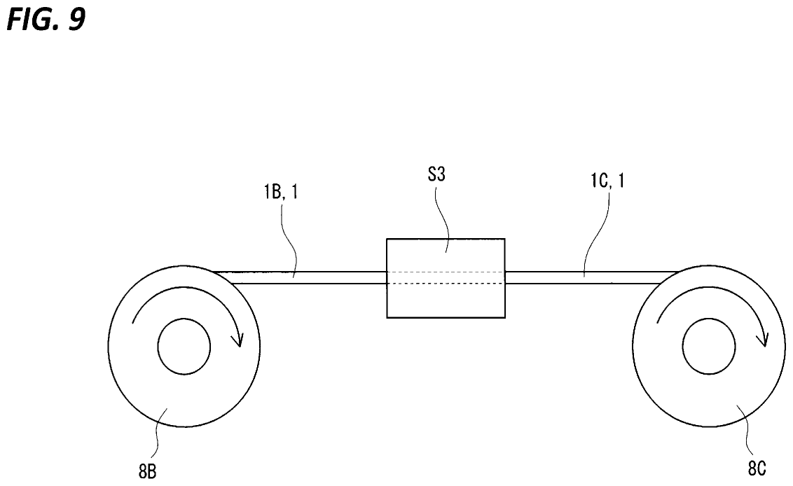

The winding structure in which the long body 1 shown in FIG. 4 is wound on the reel 8 particularly is obtained by further performing a third step S3 shown in FIG. 9 after the second step S2.

<<First Step>>

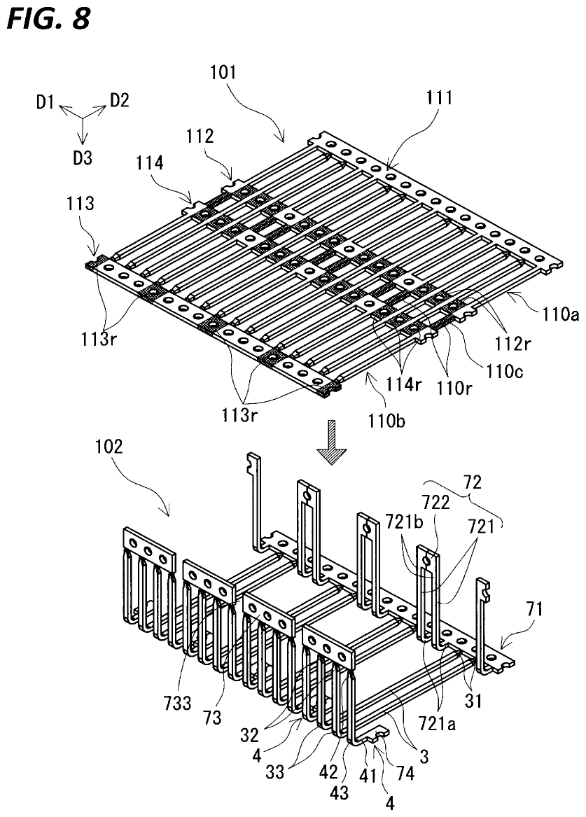

The first step S1 is a step of fabricating a second base material 102 by applying cutting, bending, embossing and/or pressing to a first base material 101 shown in FIG. 8. The first base material 101 particularly is a long member.

The first base material 101 particularly is wound on a reel 8A shown in FIG. 7. The first step S1 is performed for the first base material 101 rewound from the reel 8A.

The first base material 101 includes a plurality of first rod-like pieces 110a, a plurality of second rod-like pieces 110b, a plurality of third rod-like pieces 110c, a first carrier 111, a second carrier 112, a third carrier 113 and/or a fourth carrier 114 as shown in an upper drawing of FIG. 8.

The plurality of first rod-like pieces 110a particularly are substantially arranged in parallel in the first direction D1.

The plurality of second rod-like pieces 110b particularly are substantially arranged in parallel in the first direction D1.

The plurality of third rod-like pieces 110c particularly are substantially arranged in parallel in the first direction D1.

The first direction D1 particularly is a longitudinal direction of the first base material 101.

The plurality of third rod-like pieces 110c particularly are arranged between the plurality of first rod-like pieces 110a and the plurality of second rod-like pieces 110b. Each first rod-like piece 110a, each second rod-like piece 110b and each third rod-like piece 110c particularly are arranged to substantially extend in the second direction D2 at an angle different from 0° or 180°, particularly substantially orthogonal to the first direction D1.

Each first rod-like piece 110a, each second rod-like piece 110b and each third rod-like piece 110c particularly are arranged to be connected if being extended.

The first carrier 111 particularly is arranged on a first end part in the second direction D2 of the first base material 101. Specifically, the first carrier 111 couples first end parts of the adjacent first rod-like pieces 110a. The first carrier 111 is a strip-like member.

A longitudinal direction of the first carrier 111 particularly substantially is the longitudinal direction of the first base material 101.

The second carrier 112 particularly is arranged between the plurality of first rod-like pieces 110a and the plurality of third rod-like pieces 110c. Specifically, the second carrier 112 couples second end parts of the adjacent first rod-like pieces 110a and/or couples first end parts of the adjacent third rod-like pieces 110c. The second carrier 112 is a strip-like member.

A longitudinal direction of the second carrier 112 particularly substantially is the longitudinal direction of the second base material 101.

The third carrier 113 particularly is arranged on a second end part in the second direction D2 of the first base material 101. Specifically, the third carrier 113 couples second end parts of the adjacent second rod-like pieces 110b. The third carrier 113 is a strip-like member.

A longitudinal direction of the third carrier 113 particularly substantially is the longitudinal direction of the third base material 101.

The fourth carrier 114 particularly is arranged between the plurality of second rod-like pieces 110b and the plurality of third rod-like pieces 110c. Specifically, the fourth carrier 114 couples first end parts of the adjacent second rod-like pieces 110b and/or couples second end parts of the adjacent third rod-like pieces 110c. The fourth carrier 114 is a strip-like member.

A longitudinal direction of the fourth carrier 114 particularly substantially is the longitudinal direction of the fourth base material 101.

Each of the first, second, third and fourth carriers 111, 112, 113 and 114 particularly includes a plurality of circular holes provided at intervals in the first direction D1. Each circular hole specifically is a feed hole used in winding and rewinding the first base material 101 on and from the reel 8A.

The plurality of first rod-like pieces 110a, the plurality of second rod-like pieces 110b, the plurality of third rod-like pieces 110c, the first carrier 111, the second carrier 112, the third carrier 113 and/or the fourth carrier 114 particularly are made of the same metal.

In the first step S1, the first base material 101 is first cut. In cutting, removal parts set in advance in the first base material 101 are removed.

Specifically, removal parts 110r of the third rod-like pieces 110c, removal parts 112r of the second carrier 112, removal parts 113r of the third carrier 113 and/or removal parts 114r of the fourth carrier 114 are removed. Cross-hatched parts in the upper drawing of FIG. 8 are the respective removal parts 110r, 112r, 113r and 114r.

In the first step S1, pressing is performed after cutting. In pressing, the second rod-like pieces 110b particularly are bent and/or some of the first rod-like pieces 110a particularly are bent. All of these rod-like pieces particularly are bent in the substantially same direction.

If the second rod-like pieces 110b are bent, the L-shaped first and second terminals 3, 4 are configured as shown in a lower drawing of FIG. 8.

The first terminal 3 particularly is composed of the first rod-like piece 110a, the second rod-like piece 110b, the third rod-like piece 110c, a part of the second carrier 112 and/or a part of the fourth carrier 114 in the first base material 101.

The second terminal 4 particularly is composed of the second rod-like piece 110b.

If some of the first rod-like pieces 110a are bent, the second members 72 are configured as shown in the lower drawing of FIG. 8. The first carrier 111 particularly becomes the first member 71. Parts of the second carrier 112 particularly become the coupling portions 722 of the second members 72. Parts of the third carrier 113 particularly become the third members 73. Parts of the fourth carrier 114 particularly become the fourth members 74.

The second base material 102 in which terminal groups including the plurality of first terminals 3 and the plurality of second terminals 4 arranged in parallel in the first direction D1 particularly are coupled by the first member 71, the second members 72, the third members 73 and/or the fourth members 74 is fabricated by pressing.

A vertically inverted state of the long body including the first terminals 3 and the like shown in FIG. 3 is shown in the lower drawing of FIG. 8.

<<Second Step>>

The second step S2 is a step of fabricating a long body 1B particularly by molding the dielectric members 5 (FIG. 2) at specified (predetermined or predeterminable) positions of the second base material 102 fabricated in the first step S1.

The long body 1B is the long body 1 shown in FIG. 2. The fabricated long body 1B is to be wound on a reel 8B. The reel 8B particularly is the reel 8 shown in FIG. 1. In this example, the second step S2 is performed without winding the second base material 102 fabricated in the first step S1 on the reel.

<<Third Step>>

The third step S3 is a step of fabricating a long body 1C particularly by at least partly covering the dielectric members 5 of the long body 1B fabricated in the second step S2 with the shield members 6 (FIG. 4).

The third step S3 particularly is performed for the long body 1B rewound from the reel 8B as shown in FIG. 9.

The shield member 6 can be fabricated by arranging a specified (predetermined or predeterminable) part of the long body 1B including the dielectric member 5 in a mold and injecting the constituent material (such as metal) of the shield member 6 in a molten state into the mold. Alternatively, the shield member 6 may be fabricated by arranging the specified (predetermined or predeterminable) part of the long body 1B including the dielectric member 5 in a mold and injecting an electrically conductive resin for at least partly constituting the shield member 6 into the mold. The obtained long body 1C is the long body 1 shown in FIG. 4. The fabricated long body 1C is wound on a reel 8C. The reel 8 particularly is the reel 8 shown in FIG. 1.

The long body 1 fabricated in the third step S3 is or can be supplied to an assembly process of unillustrated connectors while being wound on the reel 8.

The plurality of terminal modules 2 (FIG. 4) in the long body 1 are divided or singled-out into a form as shown in FIG. 10 when being incorporated into an unillustrated connector.

The terminal modules 2 shown in FIG. 10 particularly are obtained by removing the first member 71, the second members 72, the third members 73 and/or the fourth members 74 from the long body 1 shown in FIG. 4.

Accordingly, there is provided a long body winding structure facilitating the handling of terminal modules and excellent in productivity in a terminal module manufacturing process. Specifically, there is disclosed a long body winding structure is provided with a long body and a reel. The long body includes one or more, particularly a plurality of terminal modules arranged substantially in parallel in a first direction, a first member, a second member and a third member. The (particularly each) terminal module includes one or more, particularly a plurality of first terminals substantially arranged in parallel in the first direction and particularly at least one dielectric member at least partly covering the one or more first terminals. Specifically, the (particularly each) first terminal substantially is an L-shaped and/or rod-like piece including a first end part, a second end part and particularly a first bent portion. The dielectric member particularly at least partly covers the one or more first terminals such that the first and second end parts of each first terminal at least partly are exposed. The first member particularly is a strip-like or oblong member coupling adjacent ones of the first end parts to link the plurality of terminal modules. The second member has a base end part coupled to the first member and particularly is arranged to substantially extend in the same direction as second sections from the second end parts to the first bent portions. The third member specifically couples the second end parts of each terminal module.

### Effects of Embodiment

Since the plurality of terminal modules 2 particularly are coupled by the first member 71 to configure the long body 1 in the winding structure 10 of this embodiment as shown in FIGS. 2 and 4, the plurality of terminal modules 2 need not be individually managed. Thus, the winding structure 10 facilitates the handling of the terminal modules 2 and is excellent in productivity in a manufacturing process of the terminal modules 2, e.g. the third step S3 (FIG. 9) of at least partly covering the dielectric members 5 with the shield members 6 and, further, the step of incorporating the terminal module 2 into the connector (not shown).

The winding structure 10 of this embodiment particularly satisfies one or more of the following conditions. (A) The dielectric members 5 and, further, the shield members 6 at least partly cover the first sections 35 and/or the second sections 36 of the first terminals 3. (B) The first member 71 is coupled to the first end part(s) 31 of the first terminal(s) 3. (C) The second member(s) 72 is/are so coupled to the first member 71 as to extend in the substantially same direction as the second section(s) 36 of the first terminal(s) 3. (D) The third member(s) 73 is/are coupled to the second end part(s) 32 of the first terminal(s) 3. By satisfying one or more of the above conditions (A) to (D), the first terminal(s) 3 and the second terminal(s) 4 particularly hardly contact the winding drum 81 and/or the flange portions 82 of the reel 8 and/or the intervening member 9 with the long body 1 wound on the reel 8. Therefore, a problem that the first terminal(s) 3 and/or the second terminal(s) 4 is/are broken with the long body 1 wound on the reel 8 is unlikely to occur in the winding structure 10.

The winding structure 10 of this embodiment particularly (further) satisfies one or more of the following conditions. (E) The second member(s) 72 is/are substantially parallel to the second section(s) 36 of the first terminal(s) 3. (F) The length L2 from the first section 35 of the first terminal 3 to the tip 722b of the second member 72 and the length L3 from the first section 35 to the tip 732b of the third member 73 substantially are equal. By satisfying one or both of the above conditions (E) and (F), the long body 1 particularly is hardly inclined when being mounted on the reel 8 and the long body 1 is easily wound on the reel 8.

What is claimed is:

1. A long body winding structure, comprising:
a long body; and
a reel having the long body to be wound thereon,
wherein:
the long body includes a plurality of terminal modules arranged substantially in parallel in a first direction, a first member, a second member and a third member,
each of the plurality of terminal modules includes a plurality of first terminals arranged substantially in parallel in the first direction and a dielectric member at least partly covering the plurality of first terminals,
each of the plurality of first terminals substantially is an L-shaped rod-like piece including a first end part, a second end part and a first bent portion,
a first section from the first end part to the first bent portion is arranged to substantially extend in a second direction intersecting, particularly substantially orthogonal to the first direction,
a second section from the second end part to the first bent portion is arranged to substantially extend in a third direction intersecting both the first direction and the second direction,
the dielectric member at least partly covers the plurality of first terminals such that the first and second end parts of each of the plurality of first terminals are exposed,
the first member comprises a strip-like member coupling adjacent ones of the first end parts to link the plurality of terminal modules,
the second member has a base end part coupled to the first member and is arranged to substantially extend in the same direction as the second sections, and
the third member couples the second end parts in each of the plurality of terminal modules.

2. The long body winding structure according to claim 1, wherein:
each of the plurality of terminal modules includes a plurality of second terminals arranged to sandwich the plurality of first terminals from outside in the first direction,
each of the plurality of second terminals substantially is an L-shaped rod-like piece including a third end part, a fourth end part and a second bent portion,
a section from the third end part to the second bent portion is arranged to substantially extend in the second direction,
a section from the fourth end part to the second bent portion is arranged to substantially extend in the third direction,
the long body includes a fourth member coupling adjacent ones of the third end parts in adjacent ones of the plurality of terminal modules, and/or
the third member couples the second end parts and the fourth end parts in each of the plurality of terminal modules.

3. The long body winding structure according to claim 1, wherein each of the plurality of terminal modules includes at least one shield member at least partly covering at least the dielectric member.

4. The long body winding structure according to claim 1, wherein a length from the first section to a tip of the second member and a length from the first section to a tip of the third member substantially are equal.

5. The long body winding structure according to claim 1, wherein the second member substantially is parallel to the second sections.

6. The long body winding structure according to claim 1, wherein a thickness direction of the first member substantially is the third direction.

7. The long body winding structure according to claim 1, wherein a gap is provided between the third members in adjacent ones of the plurality of terminal modules.

8. The long body winding structure according to claim 1, wherein:
the long body is to be wound in multiple layers on the reel, and
the long body winding structure comprises at least one intervening member at least partly arranged between turns of the long body adjacent in a radial direction of the reel.

9. The long body winding structure according to claim 8, wherein the intervening member is made of a tape material continuous in a winding direction.

10. The long body winding structure according to claim 1, wherein the long body is so to be wound that a tip of the second member and a tip of the third member substantially are facing radially outwardly of the reel.

11. The long body winding structure according to claim 1, wherein the reel includes a winding drum and one or more flange portions extending the winding drum, preferably from respective end parts of the winding drum, and
wherein a length between the two flange portions preferably substantially is equal to or less than about 1.5-fold of a width of the long body.

12. A long body, which includes a plurality of terminal modules arranged substantially in parallel in a first direction, a first member, a second member and a third member, wherein:
each of the plurality of terminal modules includes a plurality of first terminals arranged substantially in parallel in the first direction and a dielectric member at least partly covering the plurality of first terminals,
each of the plurality of first terminals substantially is an L-shaped rod-like piece including a first end part, a second end part and a first bent portion,
a first section from the first end part to the first bent portion is arranged to substantially extend in a second direction intersecting, particularly substantially orthogonal to the first direction,
a second section from the second end part to the first bent portion is arranged to substantially extend in a third direction intersecting both the first direction and the second direction,
the dielectric member at least partly covers the plurality of first terminals such that the first and second end parts of each of the plurality of first terminals are exposed,
the first member comprises a strip-like member coupling adjacent ones of the first end parts to link the plurality of terminal modules,
the second member has a base end part coupled to the first member and is arranged to substantially extend in the same direction as the second sections, and
the third member couples the second end parts in each of the plurality of terminal modules.
